(19) United States
(12) Patent Application Publication
(10) Pub. No.: US 2014/0291177 A1
(43) Pub. Date: Oct. 2, 2014

(54) FOLDABLE PROTECTION COVER FOR SUPPORTING DEVICE

(71) Applicant: Samsung Electronics Co., Ltd., Suwon-si (KR)

(72) Inventors: Jungwan KO, Seongnam-si (KR); Hyunju SHIN, Busan (KR); Taewan KIM, Seoul (KR)

(73) Assignee: Samsung Electronics Co., Ltd., Suwon-si (KR)

(21) Appl. No.: 14/224,602

(22) Filed: Mar. 25, 2014

(30) Foreign Application Priority Data
Mar. 28, 2013 (KR) 10-2013-0033466

(51) Int. Cl. H05K 5/02

(52) U.S. Cl. CPC H05K 5/0234
USPC 206/45.23

(57) ABSTRACT

A foldable protection cover for supporting a device is provided. The foldable protection cover supports a device having a window at a front surface, and includes a panel cover fastened to one surface of the device and formed with a plurality of panels that cover the window and in which the plurality of panels are bent based on a folding line formed between adjacent panels, and a fixing member provided at one surface of the panel cover and that fixes one surface of the panel cover at one surface of the device so as to support the device by the bent panel cover.

### CROSS-REFERENCE TO RELATED APPLICATION(S)

This application claims the benefit under 35 U.S.C. §119(a) of a Korean patent application filed on Mar. 28, 2013 in the Korean Intellectual Property Office and assigned Serial number 10-2013-0033466, the entire disclosure of which is hereby incorporated by reference.

### TECHNICAL FIELD

The present disclosure relates to a protection cover for supporting a device.

### BACKGROUND

In general, a tablet Personal Computer (PC), which is a typical mobile terminal, is manipulated using a touch screen instead of a keyboard or a mouse. The tablet PC may be less convenient than a netbook computer or a laptop computer for work, but has better portability than netbook computers or laptop computers and thus a demand for the tablet PC by students and office workers has arisen.

Available tablet PCs include Galaxy Tab™ of Samsung Electronics, iPad™ of Apple Inc., Identity tab of Korean corporation KT, BlackBerry™ Playbook of RIM, Slate of Hewlett-Packard, Folio 100 of Toshiba, Asus Eeepad of Asus, i-station Z3D of Korean corporation I-STATION Corp., and Optimus pad of LG Electronics. These and other companies have also developed, or are developing, other tablet PCs.

As many functions are gradually converged in the tablet PC, users use functions such as Digital Multimedia Broadcasting (DMB), movie reproduction, image viewing, and photographing through the tablet PC. The tablet PC has been used for various purposes, such as an input of text through a virtual keyboard displayed on a touch screen, drawing of pictures using a stylus touch pen, or reading of an e-book.

As the tablet PC has a large display, a weight of the tablet PC increases and thus it is inconvenient to use the tablet PC while carrying for a long time. Because the tablet PC has a panel shape of an exposed display, when carrying the tablet PC, the display may be easily broken. Accordingly, a support device that can support the tablet PC for user convenience, stable portability, and storage has been developed.

As a size and a weight of a device increase, such a device support device should be provided to stably support the device, and a structure of the device support device should be able to change to correspond to an angle to support the device according to a user's use.

Accordingly, a cover is desired that supports the device in a multi angle according to a user's various uses while having no influence on operation of the device and that does not separate from the device when supporting or storing the device and that can conveniently carry.

The above information is presented as background information only to assist with an understanding of the present disclosure. No determination has been made, and no assertion is made, as to whether any of the above might be applicable as prior art with regard to the present disclosure.

### SUMMARY

Aspects of the present disclosure are to address at least the above-mentioned problems and/or disadvantages and to provide at least the advantages described below. Accordingly, an aspect of the present disclosure is to provide a foldable protection cover for supporting a device that supports the device in various angles according to a user's use and that can prevent sliding when close contacting with the device or that can prevent separation from a window even when storing the device.

Another aspect of the present disclosure is to provide a foldable protection cover for supporting a device that can use as a cradle of the device and that protects a window and that does not have an electrical influence on operation of the device.

In accordance with an aspect of the present disclosure, a foldable protection cover for supporting a device having a window at a front surface is provided. The foldable protection cover includes a panel cover fastened to one surface of the device and formed with a plurality of panels that cover the window and in which the plurality of panels are bent based on a folding line formed between adjacent panels, and a fixing member provided at one surface of the panel cover and that fixes one surface of the panel cover at one surface of the device so as to support the device by the bent panel cover.

In accordance with another aspect of the present disclosure, a system is provided. The system includes a device including a screen arranged on a front surface and a recess arranged on one side of a rear surface, and a foldable protection cover including a panel cover formed with a plurality of panels that cover the screen and in which the plurality of panels are bent based on a folding line formed between adjacent panels and a fixing member provided at one surface of the panel cover and that fixes one surface of the panel cover at the recess of the rear surface of the device so as to support the device by the bent panel cover.

Other aspects, advantages, and salient features of the disclosure will become apparent to those skilled in the art from the following detailed description, which, taken in conjunction with the annexed drawings, discloses various embodiments of the present disclosure.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a diagram illustrating a device and a foldable protection cover for supporting a device according to an embodiment of the present disclosure;

FIG. 2 is a rear view illustrating a rear surface of a device to which the foldable protection cover for supporting the device is fastened according to an embodiment of the present disclosure;

FIG. 3 is a front view illustrating a front surface of a device to which the foldable protection cover for supporting the device is fastened according to an embodiment of the present disclosure;

FIG. 4 is a diagram illustrating an inner surface of the foldable protection cover for supporting a device according to an embodiment of the present disclosure;

FIG. 5 is a diagram illustrating a structure of a fixing member according to another embodiment of the present disclosure;

FIG. 6 is a diagram illustrating a panel cover bent by a first folding line according to an embodiment of the present disclosure;

FIG. 7 is a perspective view illustrating a panel cover bent by first and second folding lines to support a device according to an embodiment of the present disclosure; and

FIG. 8 is a perspective view illustrating a structure of a panel cover according to an embodiment of the present disclosure.

The same reference numerals are used to represent the same elements throughout the drawings.

### DETAILED DESCRIPTION

The following description with reference to the accompanying drawings is provided to assist in a comprehensive understanding of various embodiments of the present disclosure as defined by the claims and their equivalents. It includes various specific details to assist in that understanding, but these are to be regarded as merely exemplary. Accordingly, those of ordinary skill in the art will recognize that various changes and modifications of the various embodiments described herein can be made without departing from the scope and spirit of the present disclosure. In addition, descriptions of well-known functions and constructions may be omitted for clarity and conciseness.

The terms and words used in the following description and claims are not limited to the bibliographical meanings, but are merely used by the inventor to enable a clear and consistent understanding of the present disclosure. Accordingly, it should be apparent to those skilled in the art that the following description of various embodiments of the present disclosure is provided for illustration purposes only and not for the purpose of limiting the present disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

A foldable protection cover for supporting a device according to an embodiment of the present disclosure covers a window of an electronic device when storing or carrying the electronic device, thereby protecting the window from an external impact or scratches. When viewing an image or writing a text through the electronic device, by bending the protection cover, the foldable protection cover may be used as a cradle of a multi angle.

The foldable protection cover may include a fixing member that generates friction with, or adheres to, a surface in close contact with the device when supporting the device, thereby preventing a sliding phenomenon from occurring.

Further, as a fixing member provided in the protection cover can freely close contact with the device of different heights or can be freely separated from the device of different heights, the protection cover can support the device in multiple angles. Further, as a friction member is provided in a thin film form, an entire thickness of the protection cover does not increase due to the friction member, the protection cover provides user convenience when storing and using the device.

In an embodiment of the present disclosure, the device may include information and communication devices and multimedia devices, such as a tablet Personal Computer (PC), mobile communication terminal, mobile phone, Personal Digital Assistant (PDA), smart phone, International Mobile Telecommunication 2000 (IMT-2000) terminal, Code Division Multiple Access (CDMA) terminal, Wideband Code Division Multiple Access (WCDMA) terminal, Global System for Mobile communication (GSM) terminal, General Packet Radio Service (GPRS) terminal, Enhanced Data GSM Environment (EDGE) terminal, Universal Mobile Telecommunication Service (UMTS) terminal, digital broadcasting terminal, Automated Teller Machine (ATM), and applications thereof.

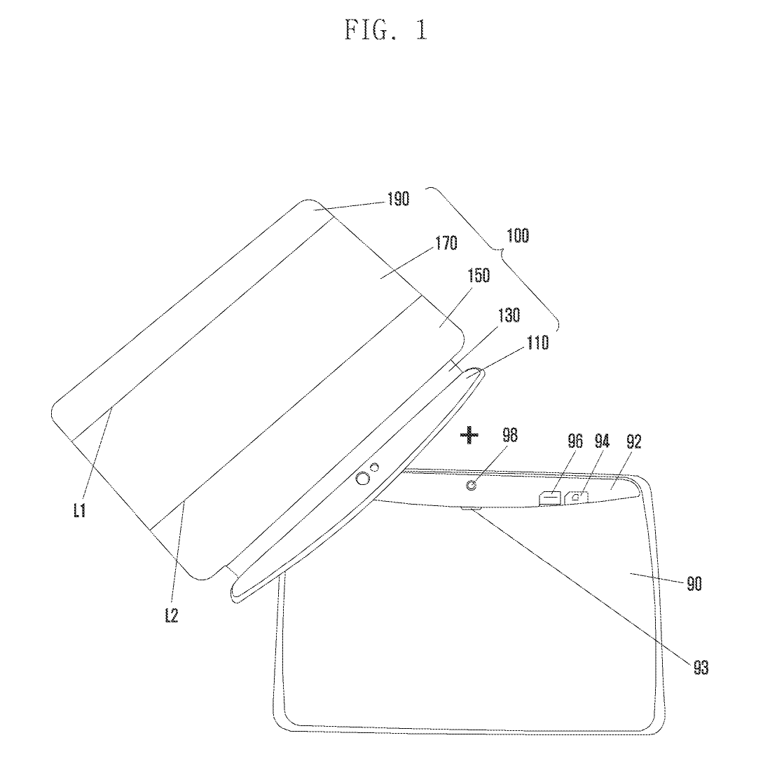

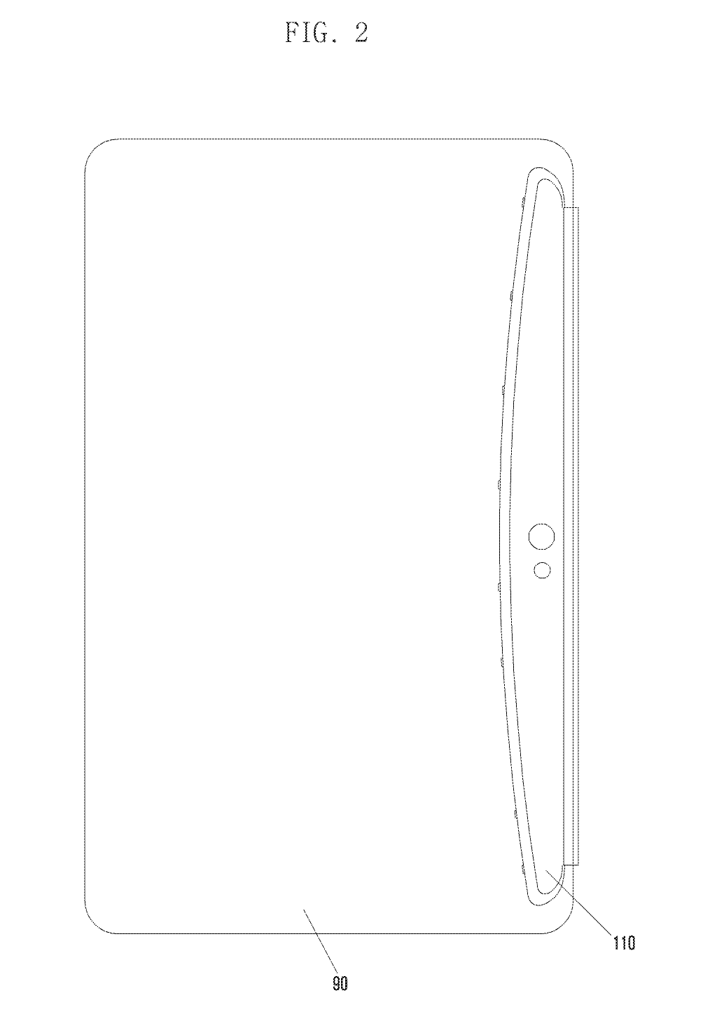

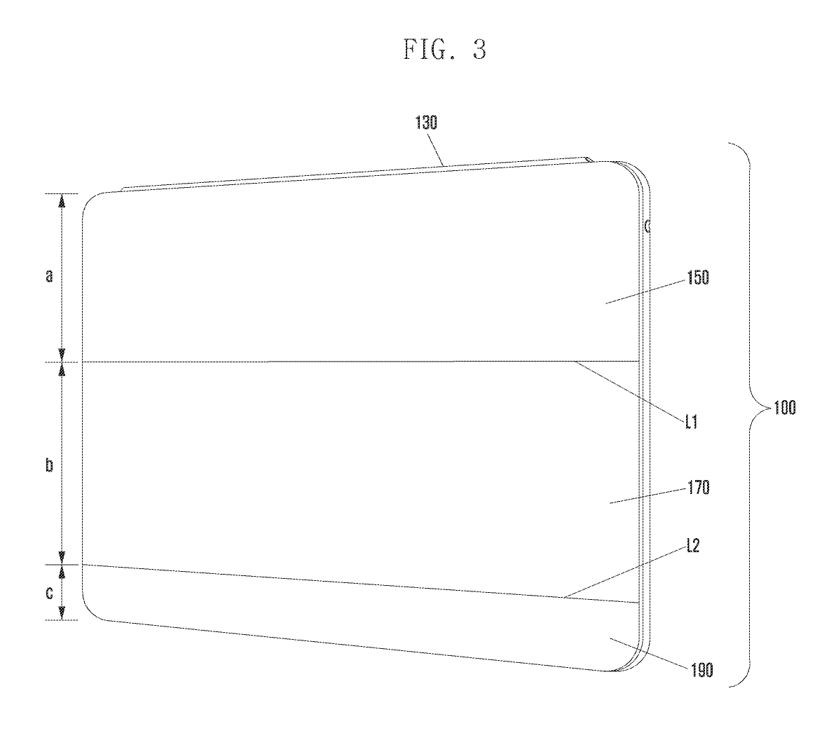

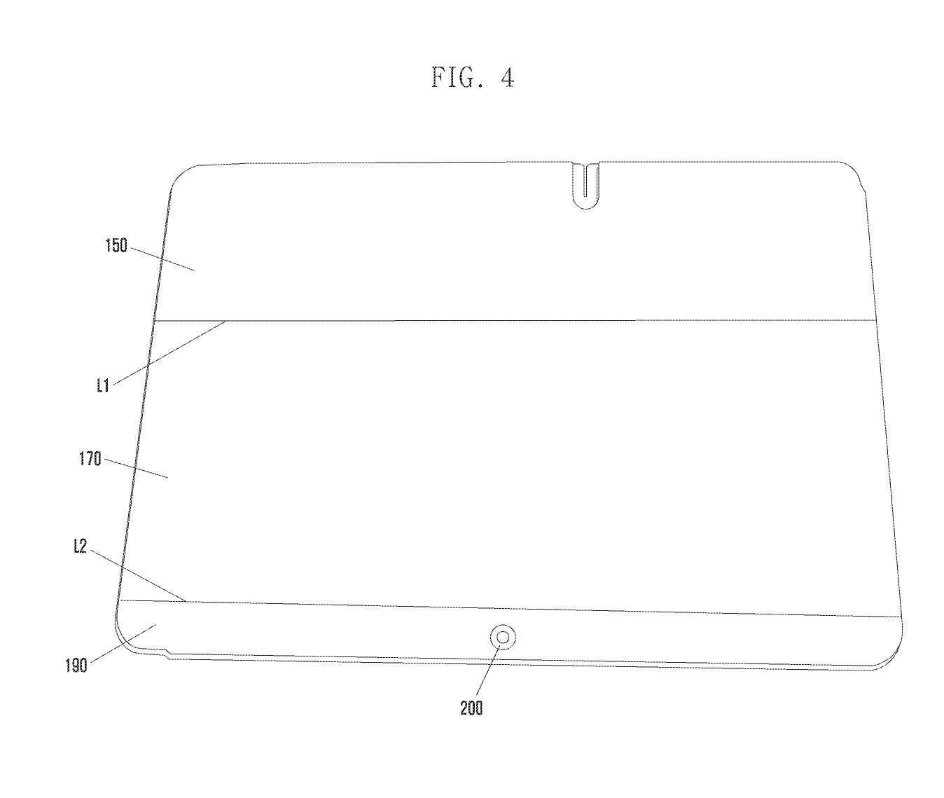

FIG. 1 is a diagram illustrating a device and a foldable protection cover for supporting a device according to an embodiment of the present disclosure, FIG. 2 is a rear view illustrating a rear surface of a device to which the foldable protection cover for supporting the device is fastened according to an embodiment of the present disclosure, FIG. 3 is a front view illustrating a front surface of a device to which the foldable protection cover for supporting the device is fastened according to an embodiment of the present disclosure, and FIG. 4 is a diagram illustrating an inner surface of the foldable protection cover for supporting a device according to an embodiment of the present disclosure.

Referring to FIGS. 1 to 4, a foldable protection cover for supporting a device according to an embodiment of the present disclosure includes a panel cover 100 and a fixing member 200 mounted in a portion of an inner surface of the panel cover 100.

The panel cover 100 includes a fastening member 110, connection member 130, and a plurality of panels 150, 170, and 190.

The fastening member 110 fastens the panel cover 100 to one surface of a device 90. For example, in an upper portion of a rear surface of the device 90, a recess 92 is formed in a predetermined depth, and when the fastening member 110 is inserted into the recess 92, the panel cover 100 is fastened to the device 90. FIG. 2 illustrates a rear surface of the device 90 in which the fastening member 110 is inserted into the recess 92 with such a method.

Referring again to FIG. 1, at least one groove 93 may be formed at one side of the recess 92, as a structure to withdraw the fastening member 110 from the recess 92. The groove 93 may be formed in a structure engraved in a predetermined depth in a portion of an edge of the recess 92, and the fastening member 110 may be withdrawn from the recess 92 as a user lifts the fastening member 110 by latching the groove 93 with a nail or a thin object.

A camera 98, input and output element 96, and marking area 94 may be further provided within the recess 92. The marking area is an area to display intrinsic information of the device and may display, for example information about quality assurance of the device and information about a serial number of the device. The input and output element is provided to input and output from the device, and a card type element may be generally used as the input and output element. The input and output element may be, for example a Subscriber Identity Module (SIM) card or a Universal Subscriber Identity Module (USIM) card that stores personal information to provide various services such as authentication, fare levy, and a security function to a mobile communication service subscriber.

Further, the input and output element is a memory card that stores and provides information and may be a storage media such as a Security Digital (SD) card, Micro-SD memory card, Mini SD memory card, Compact Flash (CF) card, Memory Stick (MS) card, Smart Media (SM) card, and MultiMedia Card (MMC).

Although not shown, unlike a structure shown in FIG. 1, the fastening member 110 may be fixed to a battery cover of the device 90 or may be provided in an integral cover form with a battery cover.

The connection member 130 connects the fastening member 110 and the plurality of panels 150, 170, and 190. The connection member 130 may be made of a material having predetermined elasticity and flexibility so that the plurality of panels may rotate in a direction of a front surface or a rear surface of the device 90.

The connection member 130 may be fastened to the fastening member 110 through a bonding method such as adhesive, bonding, hook, fusion-bonding, and zipper, and may be detachably coupled to the fastening member 110, but a coupling method is not limited thereto.

The connection member 130 may be formed with, for example at least one of rubber, urethane, silicon, leather, and fiber.

The plurality of panels may be formed with a first panel 150, second panel 170, and third panel 190, but the number of the panel is not limited thereto.

The first to third panels 150-190 are arranged in the same direction from an upper end portion to a lower end portion of the device and have a structure including folding lines L1 and L2 between each panel. The first to third panels 150-190 include a first folding line L1 formed between the first panel 150 and the second panel 170 and a second folding line L2 formed between the second panel 170 and the third panel 190.

In the first panel to third panels 150-190, lengths of each panel may formed differently in a direction bent by the first and second folding lines L1 and L2. For example, as shown in FIG. 3, when a length ratio of a length width of the first panel 150 is a, a length ratio of a length width of the second panel 170 is b, and a length ratio of a length width of the third panel 190 is c, a length size of the first panel to third panels 150-190 may be represented with b>a>c.

A length ratio of a length width of the first panel to third panels 150-190 may be changed according to a support angle of the device to embody when supporting the device.

A portion of the panel cover 100 facing the first panel to third panels 150-190 may be formed with a covering that integrally encloses the first panel to third panels 150-190 and the first and second folding lines L1 and L2 disposed between the panel. The covering may be formed with at least one of rubber, urethane, silicon, leather, and fiber. The covering may be formed integrally with the connection member 130.

The covering may be used for a portion corresponding to an outer surface of the panel cover 100, and in a portion corresponding to an inner surface of the panel cover 100, i.e., in a portion in which the panel cover 100 faces a window of the device, at least one of a relatively soft material, such as microfiber, chamois, artificial leather, and suede may be provided. By covering an inner surface of the panel cover 100 with such a material, a window of the device may be protected from scratches.

The first to third panels 150-190 may be formed with the covering and a material mounted within the covering and relatively harder than that of the covering. The hard material may use, for example, at least one of paper, plastic, leather, rubber, silicon, fiber, urethane, and polycarbonate of a predetermined thickness or more or various combinations thereof. The first to third panels 150-190 may be formed with a material that does not have an electrical influence on operation of an electronic device.

The folding lines L1 and L2 may be formed with the covering that encloses empty space between each panel of the first panel to third panels 150-190. Thereby, the folding lines L1 and L2 may be formed in an easy structure for bending and folding.

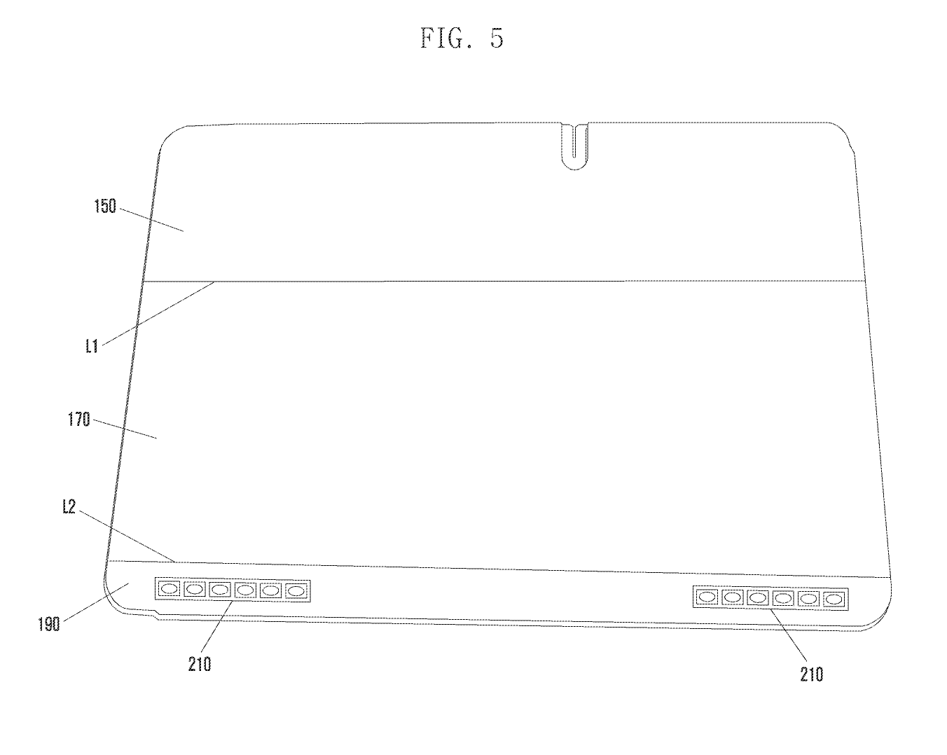

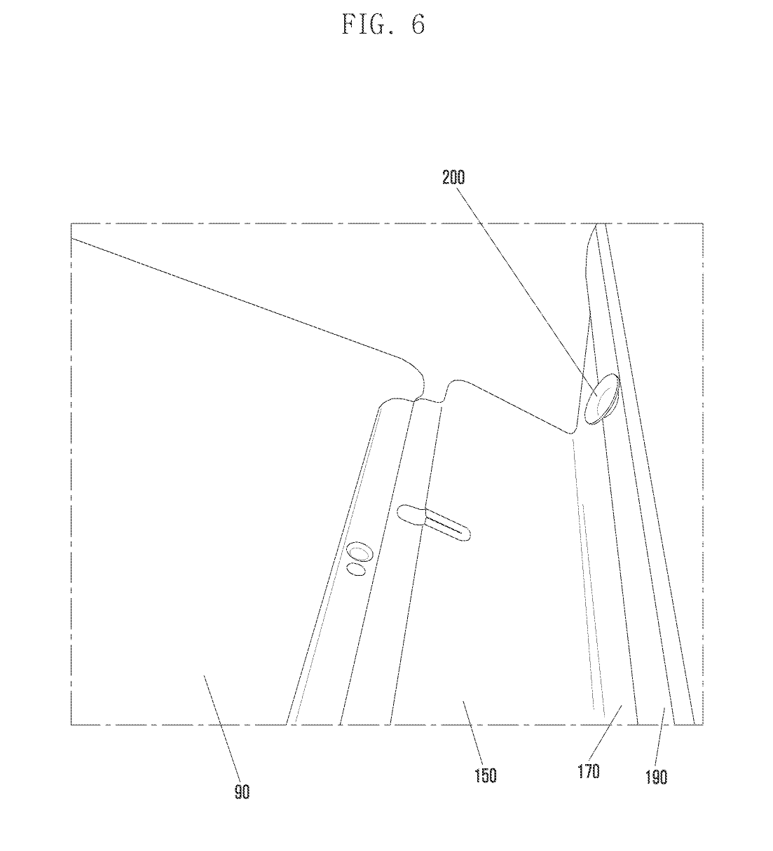

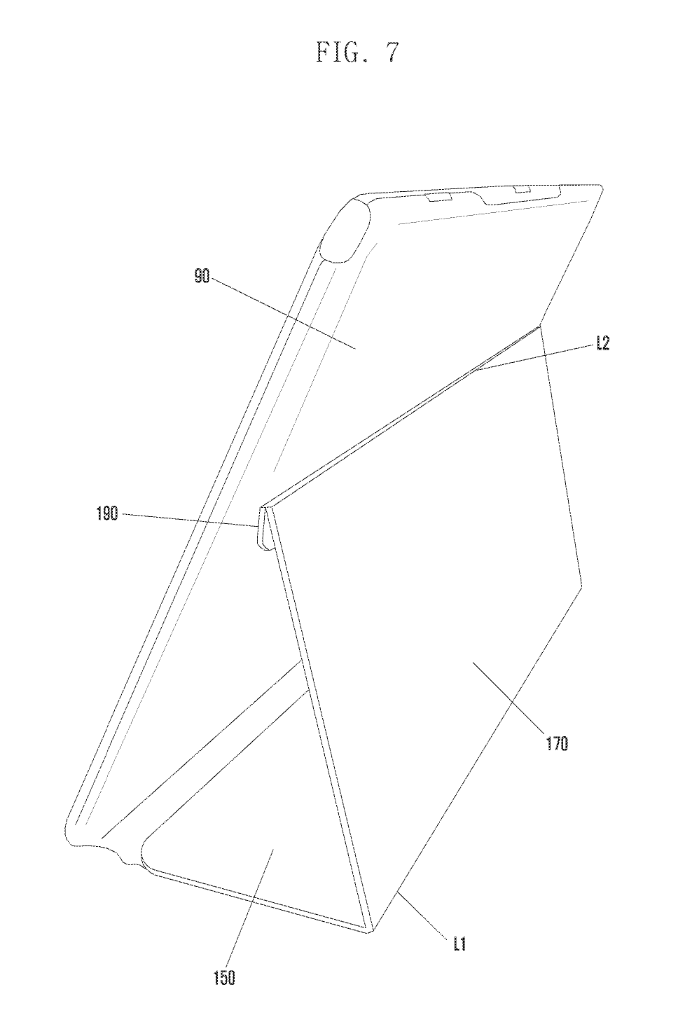

FIG. 5 is a diagram illustrating a structure of a fixing member according to another embodiment of the present disclosure, FIG. 6 is a diagram illustrating a panel cover bent by a first folding line according to an embodiment of the present disclosure, and FIG. 7 is a perspective view illustrating a panel cover bent by first and second folding lines to support a device according to an embodiment of the present disclosure.

Referring to FIGS. 5-7, the fixing member 200 may be provided to a portion of an inner surface of the panel cover 100. The fixing member 200 may be provided to one surface of the panel cover 100 facing the device 90 in a state in which the panel cover 100 is bent by bending of the first and second folding lines L1 and L2. For example, the fixing member 200 may be provided to a portion of an inner surface of the third panel 190.

The fixing member 200 may be provided at a central position of an inner surface of the third panel 190, as shown in FIG. 4, and may be provided in a plurality of areas separated by a predetermined gap from an inner surface of the third panel 190, as shown in FIG. 5.

The fixing member 200 of FIG. 5 may be provided with a fixed film 210 of a film form. Even if such a fixed film 210 is provided at an inner surface of the panel cover 100, the fixed film 210 may not have a large influence on an entire thickness of the panel cover 100.

The fixed film 210 may be provided at a surface of an inner surface of the third panel 190 with a method such as adhesive, fusion-bonding, double-sided tape, and suture, or may be provided in a form inserted into a groove formed in a portion of an inner surface of the third panel 190; however, a mounting method of the fixed film 210 is not limited thereto.

The fixed film 210 may be provided in a form in which, for example, a plurality of fixing members of a thin and small size are disposed with separated by a predetermined gap.

Although not shown, the fixed film 210 may be widely spread at an entire inner surface of the third panel 190 in an integral fixing member or a structure in which a plurality of fixing members are separated by a predetermined gap. The fixed film 210 may be provided in an entire width direction of the third panel 190, but a mounting position of the fixed film 210 is not limited thereto.

When the fixing member 200 and the fixed film 210 contact with another object, the fixing member 200 and the fixed film 210 may provide a friction member that may cause a predetermined friction between a surface of the another object and these surfaces. Alternatively, when the fixing member 200 and the fixed film 210 contact with another object, the fixing member 200 and the fixed film 210 may provide an adhering member that can removably adhere to a surface of the another object.

The fixing member 200 and the fixed film 210 according to the present embodiment may use at least one of the friction member and the adhering member, and any material that fixes one surface of the panel cover 110 to one surface of the device 100 can be applied to a protection cover of the present disclosure.

The fixing member 200 and the fixed film 210 may be formed using at least one of rubber, silicon, or silicon rubber or a combination thereof.

A function of a panel cover and a fixing member is described below with reference to FIGS. 6 and 7.

Referring to FIGS. 6 and 7, as the connection member 130 is bent, in a state in which the panel cover 100 is bent in a rear surface direction of the device 90, the first panel 150 close contacts with the ground based on the first folding line L1 and the second panel 170 is obliquely stood by a predetermined angle from the ground.

Thereafter, the third panel 190 is bent in a rear surface direction of the device 90 based on the second folding line L2. The third panel 190 is bent in a rear surface direction of the device 90 based on the second folding line L2, and an inner surface of the third panel 190 faces a rear surface of the device 90.

Accordingly, as an inner surface of the third panel 190 close contacts with a rear surface of the device 90, the device 90 is obliquely supported by a predetermined angle by the panel cover 100. In this case, when the fixing member 200 provided at an inner surface of the third panel 190 is a friction member, the friction member provides a frictional force by close contacting with a rear surface of the device 90 and thus the device 90 may be supported without sliding by the frictional force.

Alternatively, when the fixing member 200 is provided as an adhering member, as the adhering member adheres to a surface of a rear surface of the device 90, the device 90 is fixed by an adhering force and thus the fixing member 200 prevents the device 90 from being separated.

Further, because the device 90 can be easily fixed and detached at various heights, i.e., various positions of a rear surface of the device 90 due to a frictional force or an adhering force of the friction member 200, the device 90 may support the device 90 in several angles.

For example, when supporting the device 90 in a relatively low angle from the ground, a bending angle of the panel cover 100 may be adjusted so that the fixing member 200 close contacts with an upper portion of a rear surface of the device 90. In contrast, when supporting the device 90 in a relatively steep angle from the ground, a bending angle of the panel cover 100 may be adjusted so that the fixing member 200 close contacts with a lower portion of a rear surface of the device 90. An upward direction based on the center of a rear surface of the device 90 is referred to as an upper portion, and a downward direction based on the center of a rear surface of the device 90 is referred to as a lower portion.

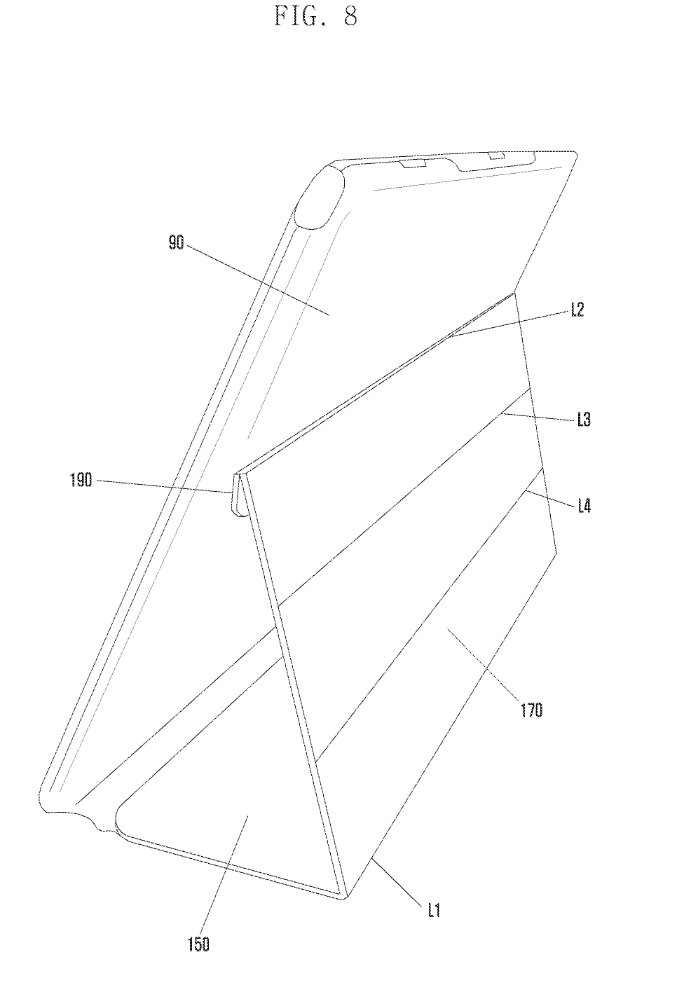

FIG. 8 is a perspective view illustrating a structure of a panel cover according to an embodiment of the present disclosure.

Referring to FIG. 8, the second panel 170 may be formed in a structure including a plurality of panels and may be formed in a structure further including folding lines L3 and L4 that can be bent between the adjacent plurality of panels.

A portion of the second panel 170 close contacts with the ground by one folding line formed within the second panel 170 and thus a height of the remaining portions of the second panel 170 stood from the ground may be changed. Thereby, a support angle of the device 90 may be adjusted.

Referring to FIG. 3, when the panel cover 100 covers a window of the device 90, the fixing member 200 mounted at an inner surface of the panel cover 100 may be fixed to the window facing thereto.

In this case, a phenomenon in which the panel cover 100 is greatly separated from the window may be prevented by a frictional force or an adhering force generated between the fixing member 200 and a surface of the window. Accordingly, a problem that a simple flat cover is easily separated from the device by sliding can be prevented.

As described above, according to the present disclosure, while protecting a window of an electronic device even without a conventionally used magnet or additional button, the electronic device can be easily supported, and a protection cover is efficient in view of cost reduction, and the electronic device can be supported in various angles in which a user wants and thus user convenience can be enhanced. Further, because the protection cover does not have an electrical and physical influence on operation of the device, reliability of the device can be improved.

As a foldable protection cover for supporting a device according to the present disclosure has a fixing member that generates a frictional force or an adhering force at a surface of the protection cover that close contacts with one surface of the device when supporting the device, the foldable protection cover can support the device in various angles according to a user's use, and when the foldable protection cover close contacts with the device, a sliding phenomenon of the device can be prevented.

Further, while a foldable protection cover for supporting a device according to the present disclosure protects a window as a window protection cover when carrying and storing the device, the protection cover close contacts with the window by a fixing member, and thus the protection cover can be prevented from being easily separated from the device.

Because a foldable protection cover for supporting a device according to the present disclosure does not have an electrical and physical influence when operating the device, reliability of the device can be improved.

While the present disclosure has been shown and described with reference to various embodiments thereof, it will be understood by those skilled in the art that various changes in form and details may be made therein without departing from the spirit and scope of the present disclosure as defined by the appended claims and their equivalents.

What is claimed is:

1. A foldable protection cover for supporting a device having a window at a front surface, the foldable protection cover comprising:
a panel cover fastened to one surface of the device and formed with a plurality of panels that cover the window and in which the plurality of panels are bent based on a folding line formed between adjacent panels; and
a fixing member provided at one surface of the panel cover and that fixes one surface of the panel cover at one surface of the device so as to support the device by the bent panel cover.

2. The foldable protection cover of claim 1, wherein the fixing member has at least one of a friction member and an adhering member.

3. The foldable protection cover of claim 1, wherein the fixing member is attached to one surface of the panel cover or is inserted into a groove formed in a portion of the panel cover.

4. The foldable protection cover of claim 1, wherein the fixing member is formed with at least one of rubber, silicon, and silicon rubber.

5. The foldable protection cover of claim 1, wherein the fixing member is provided in a film structure in a portion of an inner surface of the panel cover.

6. The foldable protection cover of claim 1, wherein the plurality of panels further comprise at least one folding line formed between adjacent panels and bent in a predetermined angle between the adjacent panels.

7. The foldable protection cover of claim 6, wherein the plurality of panels are provided with a first panel, a second panel, and a third panel from an upper end portion of the device facing the panel cover, and the plurality of panels comprise a first folding line between the first panel and the second panel and a second folding line between the second panel and the third panel.

8. The foldable protection cover of claim 7, wherein while the panel cover is positioned at a rear surface of the device, the first panel close contacts with the ground based on the first folding line, the second panel is stood in a predetermined angle from the ground, and the third panel is bent in a rear surface direction of the device based on the second folding line, and thus an inner surface of the third panel close contacts with a rear surface of the device, thereby supporting the device.

9. The foldable protection cover of claim 8, wherein the fixing member is mounted in one of a portion of an inner surface of the third panel and the entire of an inner surface of the third panel.

10. The foldable protection cover of claim 8, wherein the device is supported in different angles from the ground by the panel cover, when a height of the fixing member that close contacts with a rear surface of the device is changed.

11. The foldable protection cover of claim 8, wherein the second panel is formed with a plurality of panels comprising a folding line between adjacent panels, one of the first, second, and third panels close contacts with the ground based on the folding line, and the remaining panels are obliquely stood by a predetermined angle from the ground, thereby changing an angle in which the device is supported by the panel cover.

12. The foldable protection cover of claim 1, wherein the panel cover further comprises:
a fastening member to be fastened to one surface of the device; and
a connection member that connects the fastening member and the plurality of panels and that rotates in a front surface direction or a rear surface direction of the device.

13. A system, comprising:
a device including a screen arranged on a front surface and a recess arranged on one side of a rear surface; and
a foldable protection cover including a panel cover formed with a plurality of panels that cover the screen and in which the plurality of panels are bent based on a folding line formed between adjacent panels and a fixing member provided at one surface of the panel cover and that fixes one surface of the panel cover at the recess of the rear surface of the device so as to support the device by the bent panel cover.

14. The system of claim 13, wherein the panel cover comprises a fastening member arranged to be fastened to the rear surface of the device.

15. The system of claim 14, wherein recess includes a groove arranged to receive the fastening member.
